(19) United States
(12) Patent Application Publication
(10) Pub. No.: US 2016/0229683 A1
(43) Pub. Date: Aug. 11, 2016

(54) Manufacturing Design and Fabrication for Microfluidic Busses, Valve Arrays, Pumps, and Other Microfluidic Systems Employing Interlaminate-Spanning Structures

(71) Applicant: Saifa Phommarine, Foster City, CA (US)

(72) Inventor: Saifa Phommarine, Foster City, CA (US)

(21) Appl. No.: 15/018,854

(22) Filed: Feb. 8, 2016

Related U.S. Application Data
(60) Provisional application No. 62/113,325, filed on Feb. 6, 2015.

(51) Int. Cl. B81B 1/00

(52) U.S. Cl. CPC B81B 1/004; B81B 2201/058

(57) ABSTRACT

The present application addresses manufacturing design and fabrication techniques for active conduit-based microfluidic and micro-scale gas-flow systems comprising valves and/or pumps of arbitrary complexity, and in particular comprising complex structures such as valve arrays, bus structures, and intricate or high-replication microfluidic and micro-scale gas-flow arrangements and configurations. Of special value in implementing such complex flow-network topologies in compact volumes is the use of stack of specifically-configured laminate layers linked by electrically-operated, pneumatically operated or fluidicly-operated interlaminate-spanning flow-valve structures and pumps comprising interlaminate-spanning structure.

### CROSS REFERENCE TO RELATED APPLICATIONS

This application relies upon and claims the benefit of priority of U.S. Provisional Application Ser. No. 62/113,325, filed Feb. 6, 2015, which is incorporated by reference herein.

### COPYRIGHT & TRADEMARK NOTICES

A portion of the disclosure of this patent document may contain material, which is subject to copyright protection. Certain marks referenced herein may be common law or registered trademarks of the applicant, the assignee or third parties affiliated or unaffiliated with the applicant or the assignee. Use of these marks is for providing an enabling disclosure by way of example and shall not be construed to exclusively limit the scope of the disclosed subject matter to material associated with such marks.

### BACKGROUND OF THE INVENTION

1. Field of the Invention

This patent application generally relates to the area of microfluidic and micro-scale gas-flow systems, and in particular to manufacturing design and fabrication techniques for microfluidic and micro-scale gas-flow systems comprising valve arrays, bus structures, and other microfluidic and micro-scale gas-flow arrangements and configurations.

2. Description of Related Art

Microfluidic systems, and by extension micro-scale gas-flow systems and subsystems, hold great promise in a wide range of future applications. Many microfluidic systems are passive and contain no pumps or valves. Some microfluidic systems, and by extension micro-scale gas-flow systems and subsystems, comprise at least one valve or pump. A next generation of microfluidic systems and micro-scale gas-flow systems and subsystems is expected to comprise a large number of valves, and in some cases the valves would be arranged in arrays. Important examples include the microfluidic (and micro-scale gas-flow) buss arrangements taught in U.S. Pat. No. 8,032,258, U.S. Pat. No. 8,606,414, and U.S. Pat. No. 8,812,163, as well as software reconfigurable/software defined/software operated microfluidic (and micro-scale gas-flow) systems taught in U.S. Ser. No. 13/314,170 (published as US App 2012/0094366), U.S. Ser. No. 13/761,142 (published as 2013/0217598), U.S. Ser. No. 13/815,757 (published as 2014/027481), and U.S. Ser. No. 13/844,621 (published as US App 2014/0273191).

In one approach to the fabrication of passive conduit-based microfluidic systems, such as that taught in Hu et al. U.S. Pat. No. 6,623,860, a microfluidic system is constructed from a stack of specifically-configured laminate layers, wherein each layer can be machined and/or molded. The stack of specifically-configured laminate layers stacked together in appropriate order and with appropriate alignment and bonding form a microfluidic system comprising a plurality of vias linking passageways in among pairs of layers. Such an arrangement is analogous to multi-layer printed circuit boards commonly used in consumer and industrial electronics.

### SUMMARY OF THE INVENTION

The embodiments described herein are directed to systems and methods that substantially obviate one or more of the above and other problems associated with the conventional technology.

More particularly, embodiments described herein address manufacturing design and fabrication techniques for active conduit-based microfluidic and micro-scale gas-flow systems comprising valves and/or pumps of arbitrary complexity, and in particular comprising complex structures such as valve arrays, bus structures, and intricate or high-replication microfluidic and micro-scale gas-flow arrangements and configurations. Of special value in implementing such complex flow-network topologies in compact volumes is the use of stack of specifically-configured laminate layers linked by electrically-operated, pneumatically operated or fluidicly-operated interlaminate-spanning flow-valve structures and pumps comprising interlaminate-spanning structures.

### BRIEF DESCRIPTION OF THE DRAWINGS

The above and other aspects, features, and advantages of the present invention will become more apparent upon consideration of the following description of preferred embodiments, taken in conjunction with the accompanying drawing figures.

FIG. 1A depicts an example arrangement wherein an example on/off valve links a T-joint tap on a first channel in a first laminate layer with a T-joint tap on a second channel in a second laminate layer.

FIG. 1B depicts an example arrangement wherein an example on/off valve links a T-joint tap on a first channel in a first laminate layer with an L-joint on a second channel in a second laminate layer.

FIG. 1C depicts an example arrangement wherein an example on/off valve links an L-joint on a first channel in a first laminate layer with a T-joint tap to a second channel in a second laminate layer.

FIG. 1D depicts an example arrangement wherein an example on/off valve links an L-joint on a first channel in a first laminate layer with an L-joint on a second channel in a second laminate layer.

FIG. 2A depicts an example arrangement wherein an example valve is formed or comprised by openings and/or structures in at least one of the first laminate layer and second laminate layer described in conjunction with FIG. 1A and which can be adapted for use with the configurations of FIGS. 1B-1D.

FIG. 2B depicts an example arrangement wherein an example valve is formed or comprised by openings and/or structures in both the first laminate layer and second laminate layer described in conjunction with F FIG. 1A and which can be adapted for use with the configurations of FIGS. 1B-1D.

FIG. 2C depicts an example arrangement wherein an example valve is formed or comprised by openings and/or structures in at least an additional third laminate layer, the additional third laminate layer sandwiched between the first laminate layer and second laminate layer described in conjunction with FIG. 1A and which can be adapted for use with the configurations of FIGS. 1B-1D.

FIG. 2D depicts an example arrangement wherein an example valve is formed or comprised by openings and/or structures in at least a plurality of additional laminates layers, the plurality of additional laminates layers sandwiched between the first laminate layer and second laminate layer described in conjunction with FIG. 1A and which can be adapted for use with the configurations of FIGS. 1B-1D. FIG. 3 depicts an example arrangement of a 5-layer microfluidic device wherein each layer can be machined and/or molded and when stacked together with appropriate alignment and bonding form a microfluidic and/or micro-scale gas-flow system comprising a plurality of valves. The left half of the figure depicts an angular vantage point of the separated layers from position at the top and side, while the right half of the figure depicts a direct side view of each layer.

FIG. 4 depicts an example arrangement wherein the layers depicted in FIG. 3 are appropriately aligned and bonded to form a microfluidic and/or micro-scale gas-flow system comprising a plurality of valves.

FIG. 5 depicts a more detailed view of the individual laminate layers for the example arrangement depicted in FIG. 3.

FIG. 6 depicts details of how a deformable elastic membrane layer can be affixed atop one of the laminate layers of the example arrangement of FIG. 3; appropriate deformation of the membrane prevents flows from occurring between the fluidic/gas passage channels connecting with the valve structure.

FIG. 7 depicts an example 3-layer arrangement, which in turn can be embedded with a larger arrangement comprising more laminate layers (such as the arrangement depicted in FIG. 3) wherein at least one valve is formed or comprised by openings and/or structures in at least one side of the center laminate layer and an attached first laminate layer and at least one valve is formed or comprised by openings and/or structures in at least another side of the center laminate layer and an attached second laminate layer.

FIG. 8A depicts an example opening-spanning arrangement wherein two layers of piezoelectric material are configured to be influenced by the same electric field so as to expand and/or contract in a predetermined coordinated fashion. In one arrangement, the range of motion of expansion and contraction are amplified. In an opposite arrangement, the interface between the two layers of piezoelectric material

FIG. 8B depicts an example swaying-member or rotating-member arrangement wherein one or more layers of piezoelectric material is configured to actuate a lever element for use in locally deforming or positioning a membrane or other flow-controlling mechanical element under the control of electrical potential as part of a valve, pump, or other flow-manipulating or flow-controlling arrangement.

FIG. 8C depicts an example opening-spanning arrangement wherein one or more layers of piezoelectric material is configured to actuate a cantilever arrangement for use in locally deforming or positioning a membrane or other flow-controlling mechanical element under the control of electrical potential as part of a valve, pump, or other flow-manipulating or flow-controlling arrangement.

### DETAILED DESCRIPTION

In the following detailed description, reference is made to the accompanying drawing figures which form a part hereof, and which show by way of illustration specific embodiments of the invention. It is to be understood by those of ordinary skill in this technological field that other embodiments may be utilized, and structural, electrical, as well as procedural changes may be made without departing from the scope of the present invention. Wherever possible, the same reference numbers will be used throughout the drawings to refer to the same or similar elements.

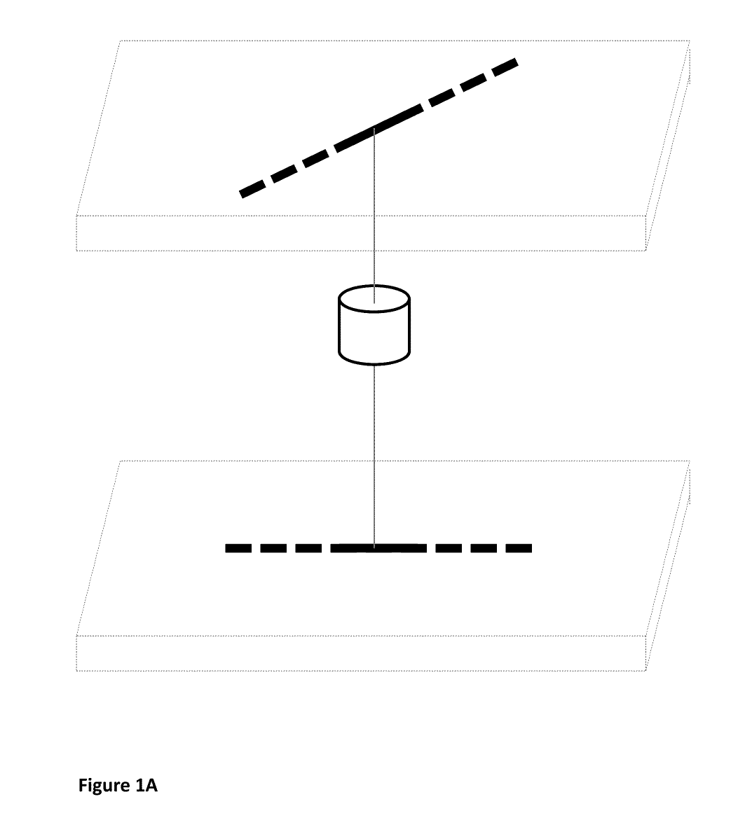

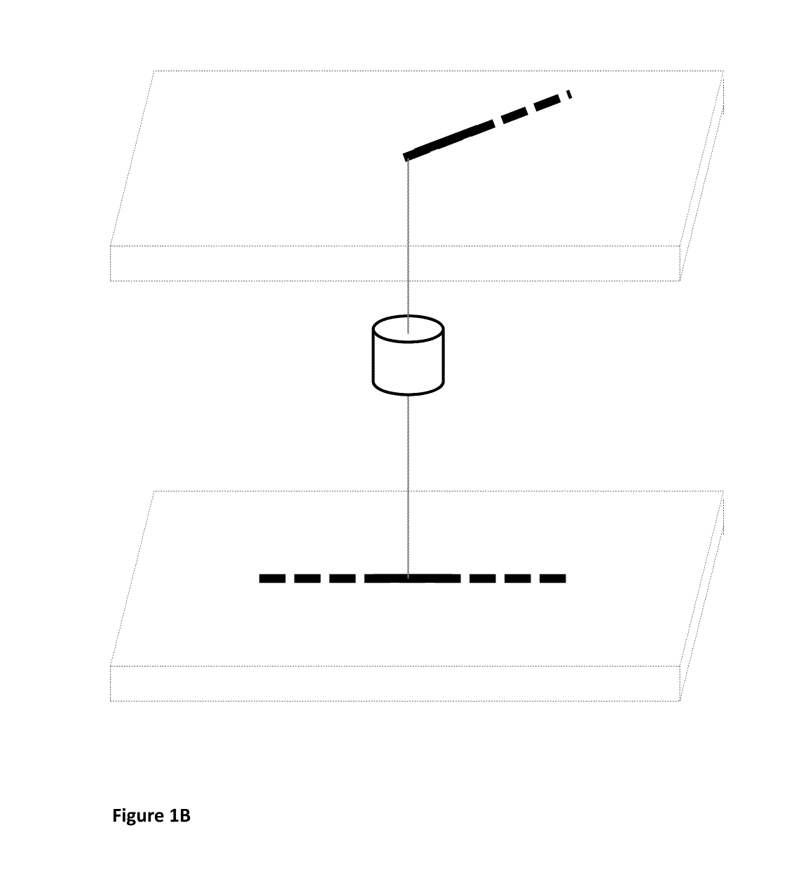

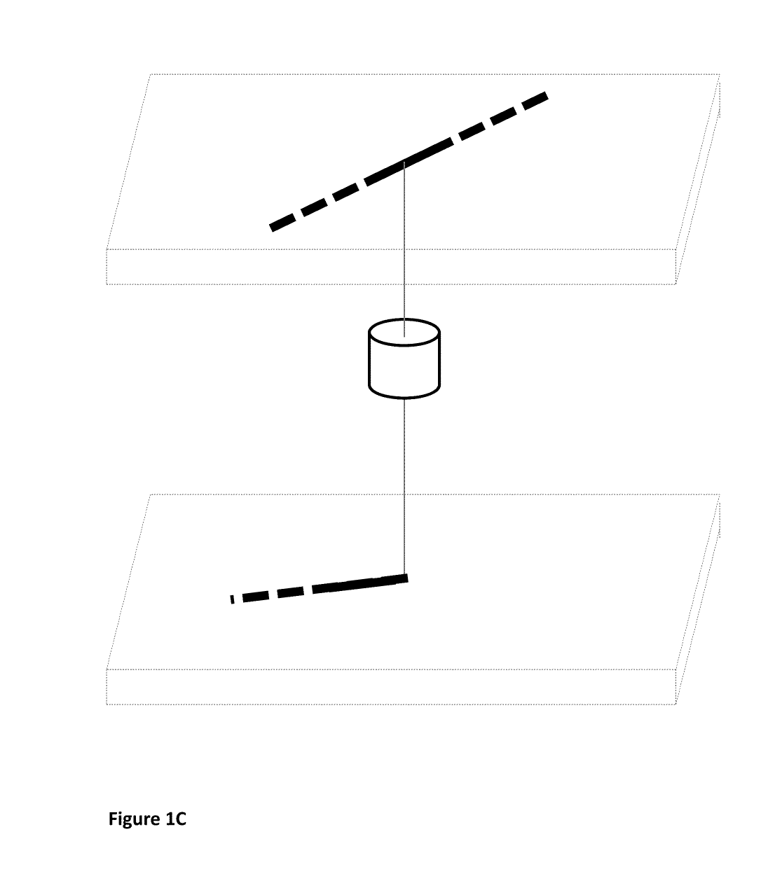

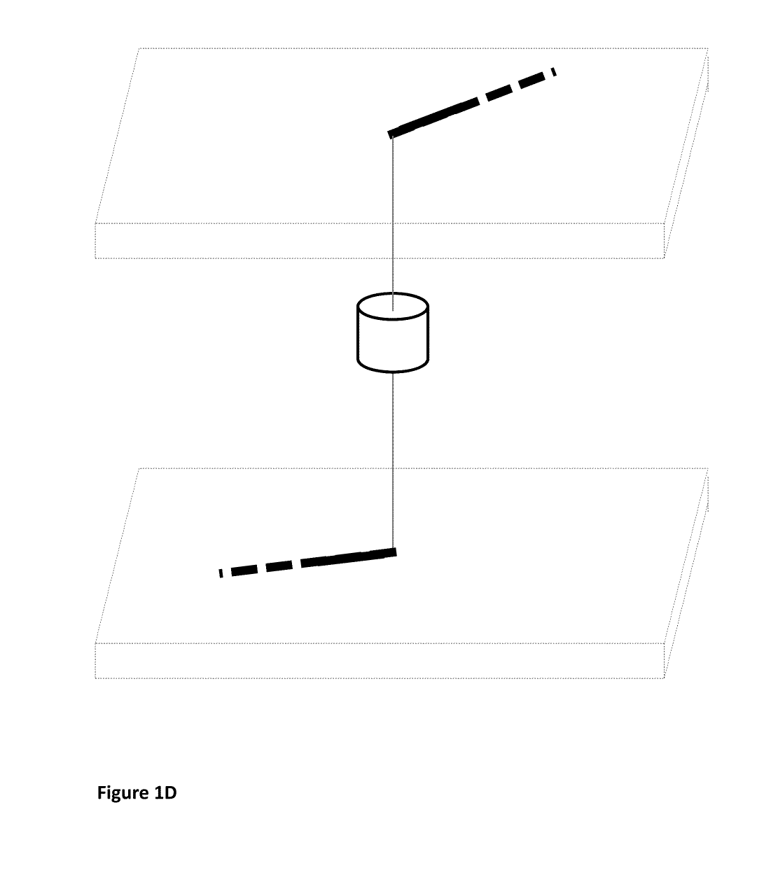

FIG. 1A depicts an example arrangement wherein an example on/off valve links a T-joint tap on a first channel in a first laminate layer with a T-joint tap on a second channel in a second laminate layer.

FIG. 1B depicts an example arrangement wherein an example on/off valve links a T-joint tap on a first channel in a first laminate layer with an L-joint on a second channel in a second laminate layer.

FIG. 1C depicts an example arrangement wherein an example on/off valve links an L-joint on a first channel in a first laminate layer with a T-joint tap to a second channel in a second laminate layer.

FIG. 1D depicts an example arrangement wherein an example on/off valve links an L-joint on a first channel in a first laminate layer with an L-joint on a second channel in a second laminate layer.

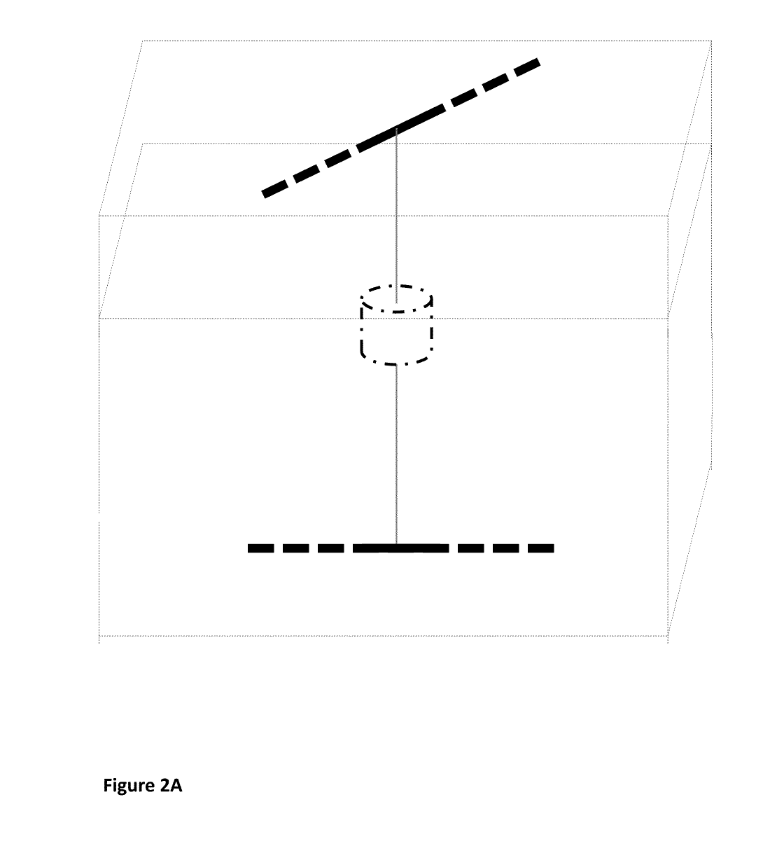

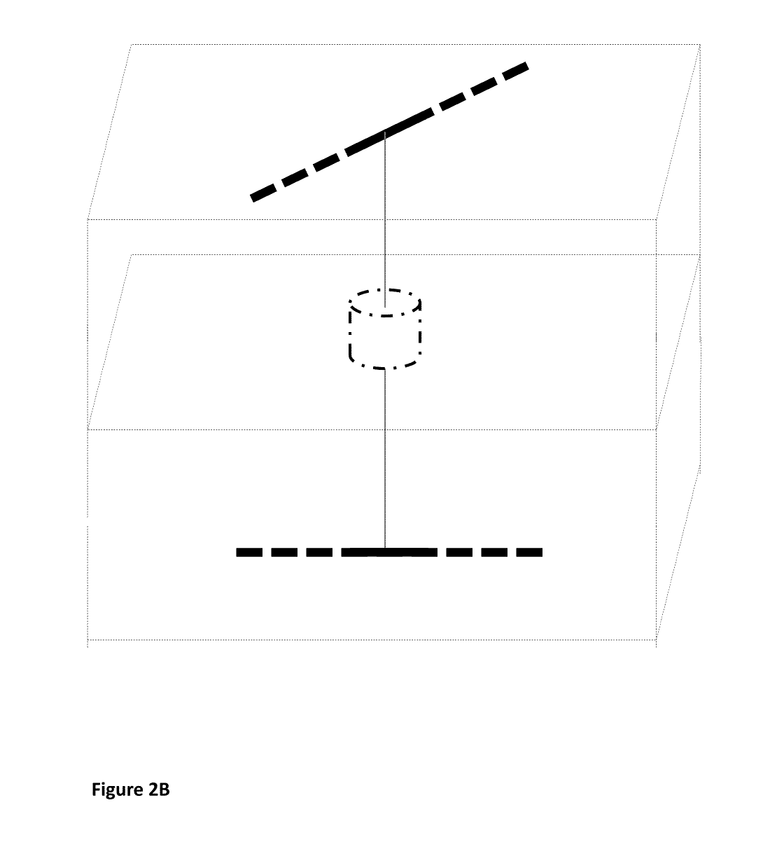

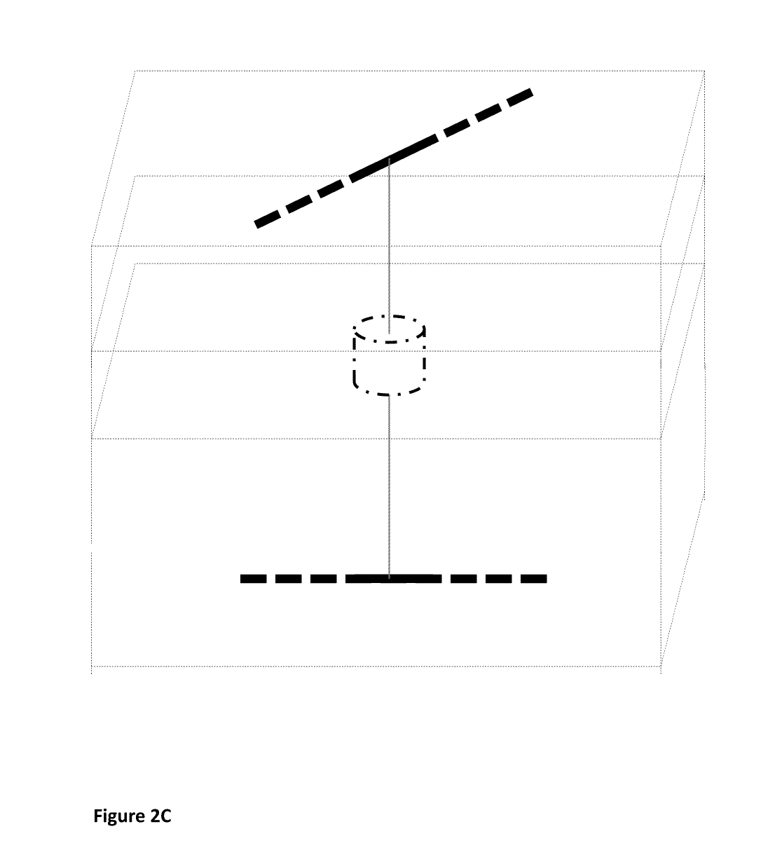

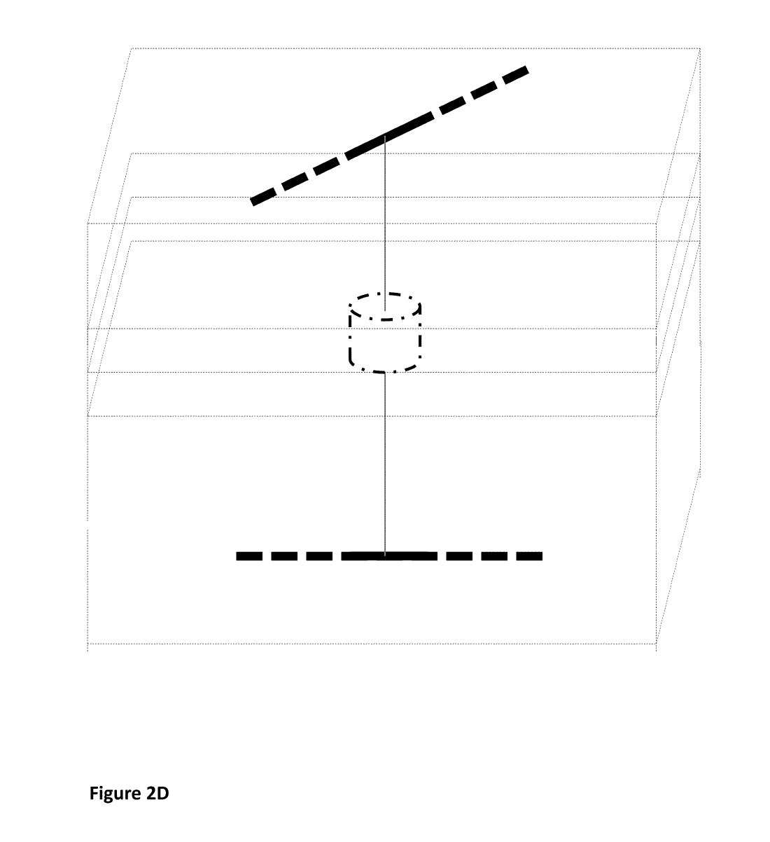

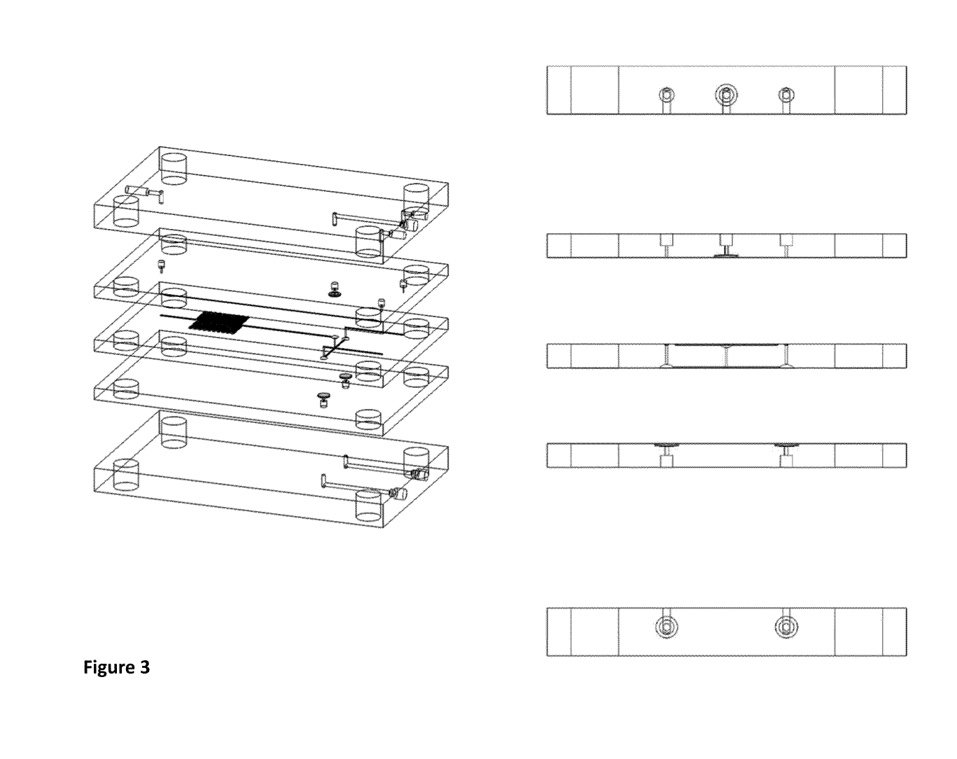

FIG. 2A depicts an example arrangement wherein an example valve is formed or comprised by openings and/or structures in at least one of the first laminate layer and second laminate layer described in conjunction with FIG. 1A and which can be adapted for use with the configurations of FIGS. 1B-1D.

FIG. 2B depicts an example arrangement wherein an example valve is formed or comprised by openings and/or structures in both the first laminate layer and second laminate layer described in conjunction with F FIG. 1A and which can be adapted for use with the configurations of FIGS. 1B-1D.

FIG. 2C depicts an example arrangement wherein an example valve is formed or comprised by openings and/or structures in at least an additional third laminate layer, the additional third laminate layer sandwiched between the first laminate layer and second laminate layer described in conjunction with FIG. 1A and which can be adapted for use with the configurations of FIGS. 1B-1D.

FIG. 2D depicts an example arrangement wherein an example valve is formed or comprised by openings and/or structures in at least a plurality of additional laminates layers, the plurality of additional laminates layers sandwiched between the first laminate layer and second laminate layer described in conjunction with FIG. 1A and which can be adapted for use with the configurations of FIGS. 1B-1D.

FIG. 3 depicts an example arrangement of a 5-layer microfludic device wherein each layer can be machined and/or molded and when stacked together with appropriate alignment and bonding form a microfluidic and/or micro-scale gas-flow system comprising a plurality of valves. The left half of the figure depicts an angular vantage point of the separated layers from position at the top and side, while the right half of the figure depicts a direct side view of each layer.

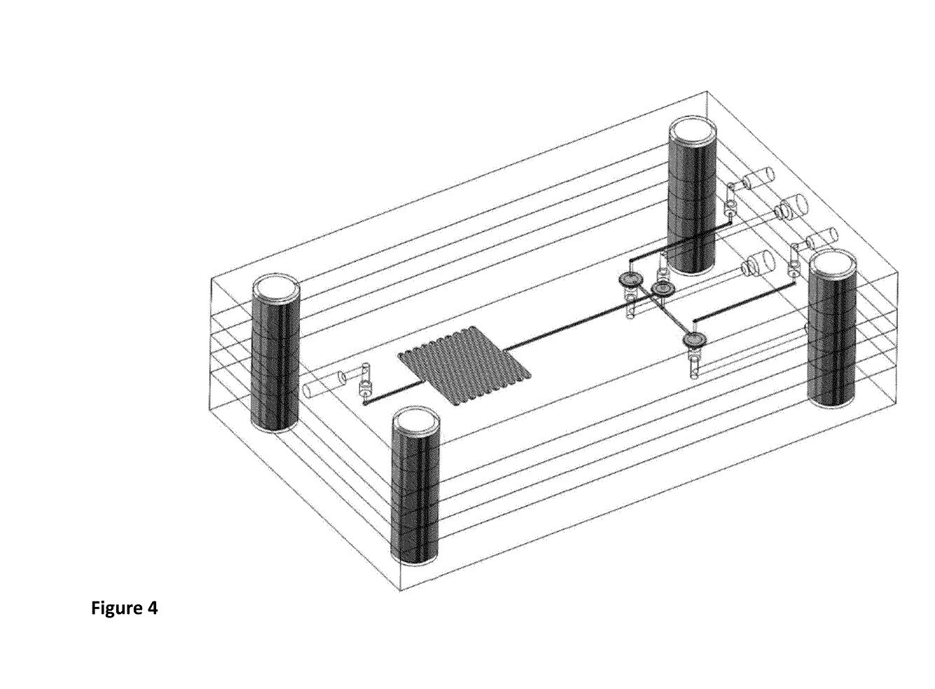

FIG. 4 depicts an example arrangement wherein the layers depicted in FIG. 3 are appropriately aligned and bonded to form a microfluidic and/or micro-scale gas-flow system comprising a plurality of valves.

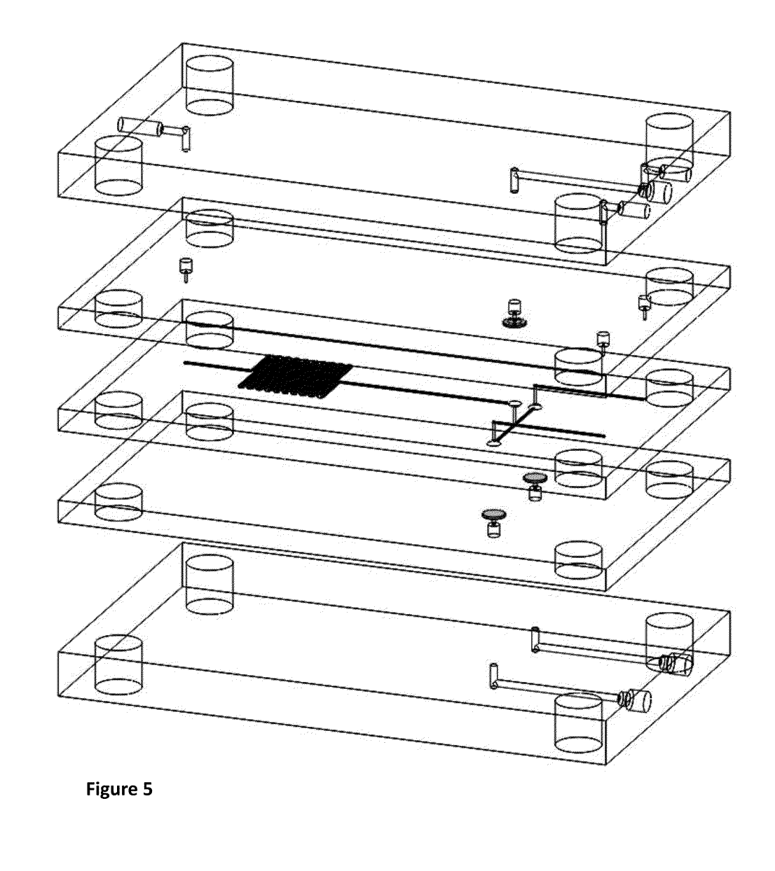

FIG. 5 depicts a more detailed view of the individual laminate layers for the example arrangement depicted in FIG. 3.

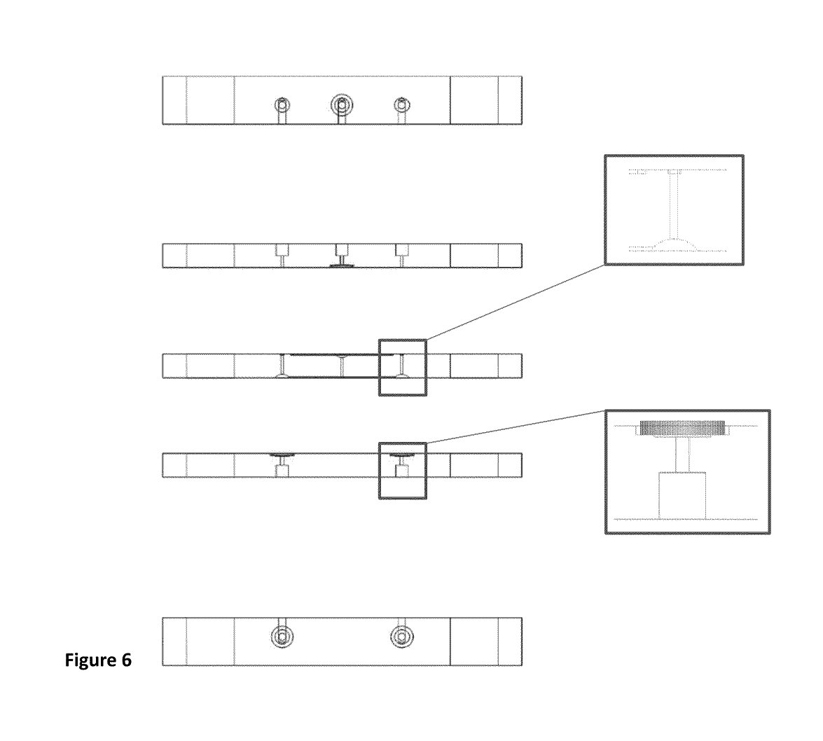

FIG. 6 depicts details of how a deformable elastic membrane layer can be affixed atop one of the laminate layers of the example arrangement of FIG. 3; appropriate deformation of the membrane prevents flows from occurring between the fluidic/gas passage channels connecting with the valve structure.

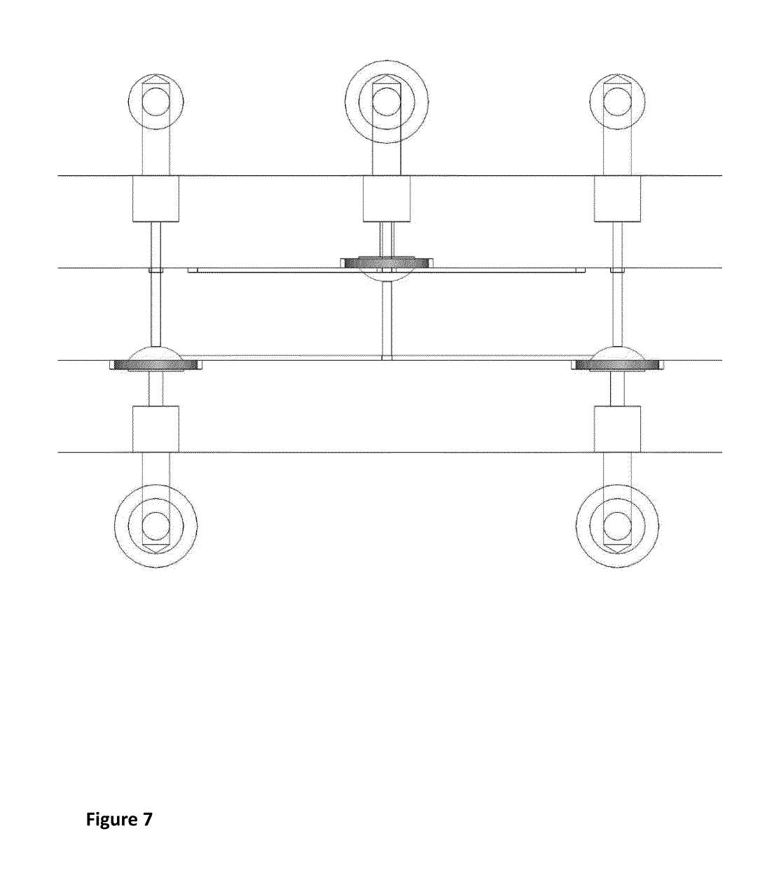

FIG. 7 depicts an example 5-layer arrangement, which in turn can be embedded with a larger arrangement comprising more laminate layers (such as the arrangement depicted in FIG. 3) wherein at least one valve is formed or comprised by openings and/or structures in at least one side of the center laminate layer and an attached first laminate layer and at least one valve is formed or comprised by openings and/or structures in at least another side of the center laminate layer and an attached second laminate layer.

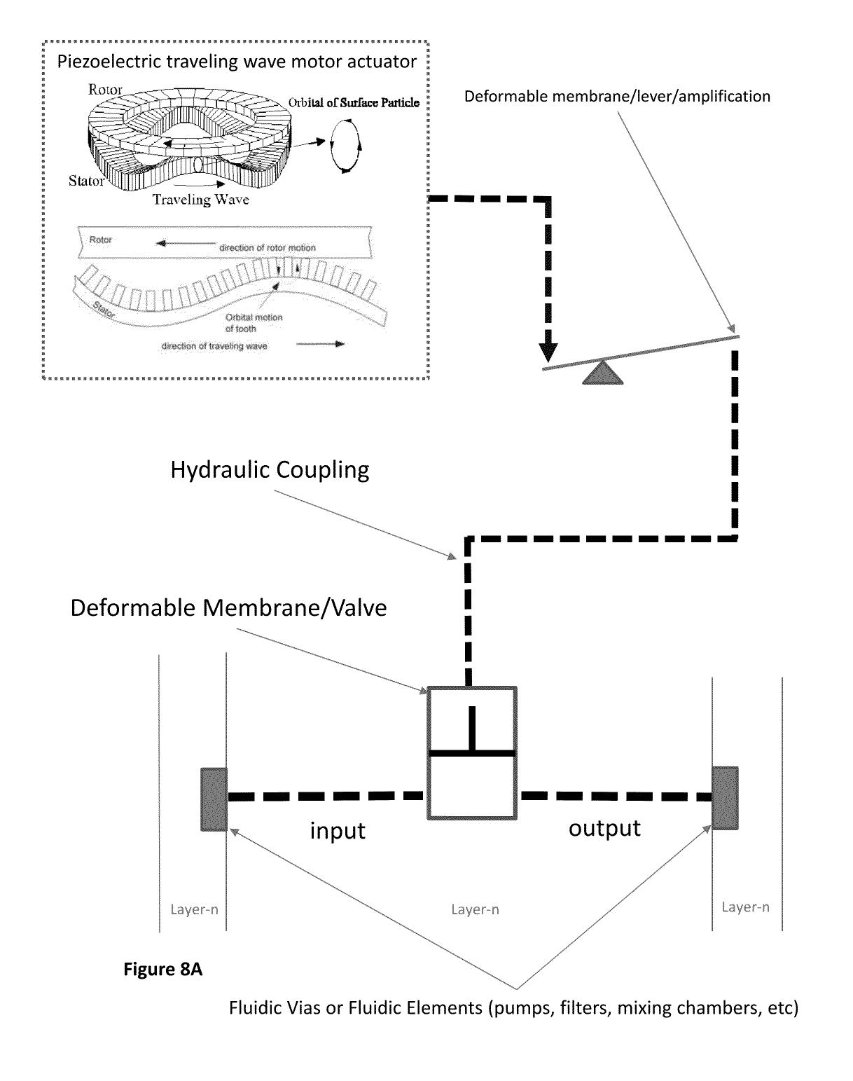

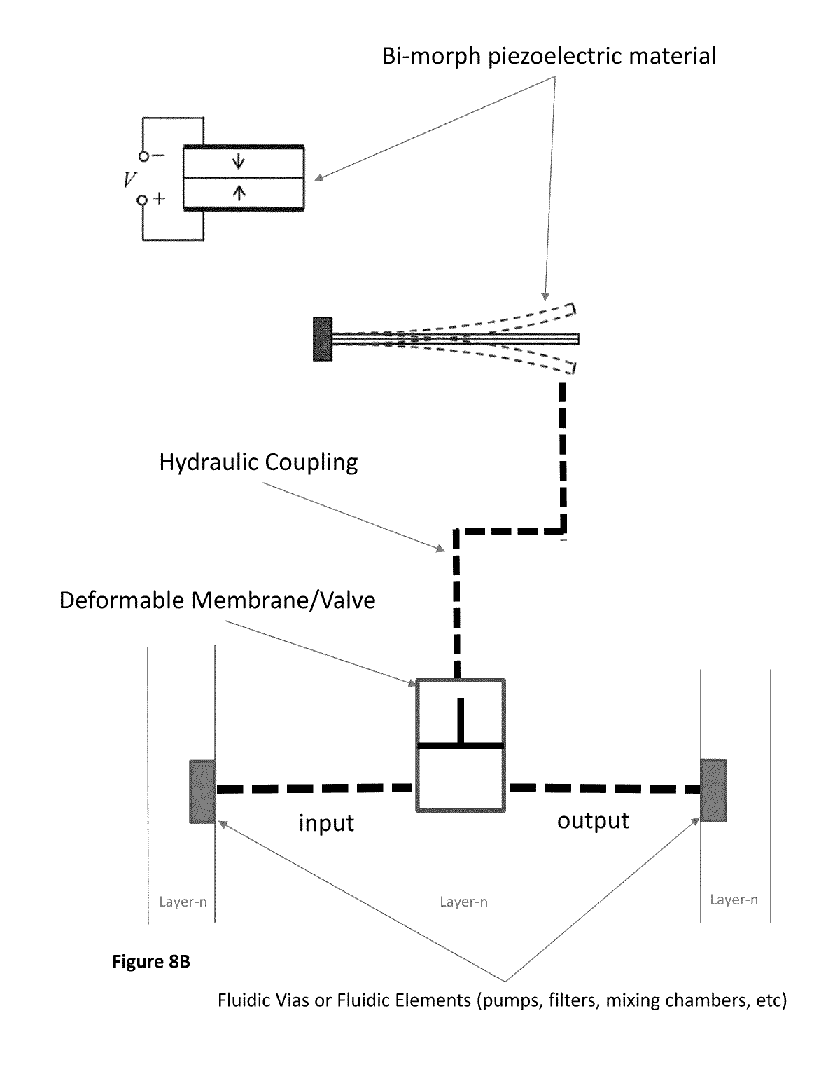

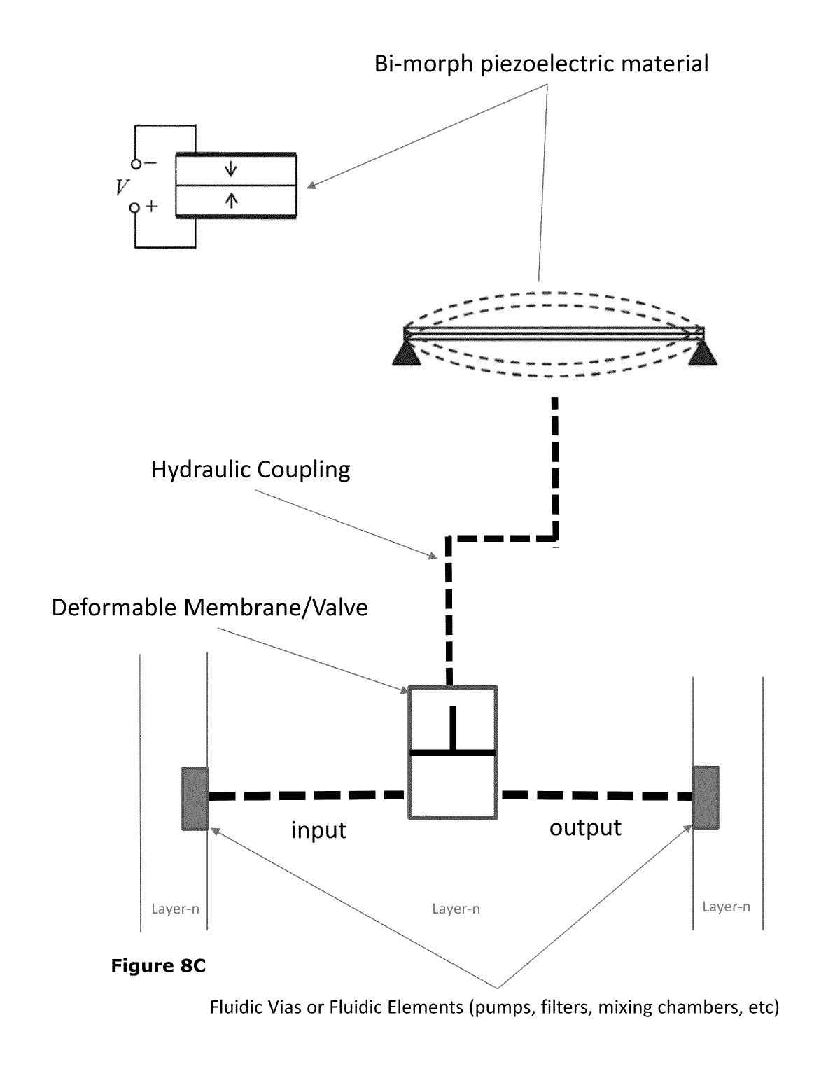

FIG. 8A depicts an example swaying-member or rotating-member arrangement wherein one or more layers of piezoelectric material is configured to actuate a lever element for use in locally deforming or positioning a membrane or other flow-controlling mechanical element under the control of electrical potential as part of a valve, pump, or other flow-manipulating or flow-controlling arrangement.

FIGS. 8B depicts an example opening-spanning arrangement wherein one or more layers of piezoelectric material is configured to actuate a cantilever arrangement by way of end mode deformation, for use in locally deforming or positioning a membrane or other flow-controlling mechanical element under the control of electrical potential as part of a valve, pump, or other flow-manipulating or flow-controlling arrangement.

FIGS. 8C depicts an example opening-spanning arrangement in a wherein one or more layers of piezoelectric material is configured to actuate a cantilever arrangement by way of center mode deformation, for use in locally deforming or positioning a membrane or other flow-controlling mechanical element under the control of electrical potential as part of a valve, pump, or other flow-manipulating or flow-controlling arrangement.

### CLOSING

While the invention has been described in detail with reference to disclosed embodiments, various modifications within the scope of the invention will be apparent to those of ordinary skill in this technological field. It is to be appreciated that features described with respect to one embodiment typically may be applied to other embodiments. Moreover, other implementations of the invention will be apparent to those skilled in the art from consideration of the specification and practice of the invention disclosed herein. Various aspects and/or components of the described embodiments may be used singly or in any combination in the design and fabrication techniques for microfluidic and micro-scale gas-flow systems comprising valve arrays, bus structures, and other microfluidic and micro-scale gas-flow arrangements and configurations. It is intended that the specification and examples be considered as exemplary only, with a true scope and spirit of the invention being indicated by the following claims.

I claim:

1. A system for active conduit-based microfluidic and micro-scale gas-flow comprising:
a first laminate layer;
a second laminate layer; and
a plurality of openings and structures located within least a plurality of additional laminates layers, the plurality of additional laminates layers sandwiched between the first laminate layer and second laminate layer,
wherein an example on/off valve links a T-joint tap on a first channel in the first laminate layer with a T-joint tap on a second channel in the second laminate layer.
